(19) United States
(12) Patent Application Publication
(10) Pub. No.: US 2007/0252729 A1
(43) Pub. Date: Nov. 1, 2007

(54) Sensing Keypad of Portable Terminal and the Controlling Method

(75) Inventors: Dong Li, League City, TX (US); Jin Guo, Cupertino, CA (US)

Correspondence Address: Dong Li, 2558 Costa Mesa Circle, League City, TX, 77573, US

(73) Assignees: Dong Li, League City, TX (US); Jin Guo, Cupertino, CA (US)

(21) Appl. No.: 11/659,918

(22) PCT Filed: Aug. 12, 2004
(86) PCT No.: PCT/CN04/00936

§ 371 Date: Feb. 10, 2007

(51) Int. Cl. H03K 17/94

(52) U.S. Cl. 341/22

(57) ABSTRACT

The present invention provides a sensing keypad of a portable terminal and its controlling method, comprising: placing at least one sensing unit in the keypad area of the portable terminal to form a sensing surface; placing at least one sensing key on the said sensing surface; when a sensing object moves on the said sensing surface, the said at least one sensing unit generates multidimensional coordinates signal corresponding to trajectory of movement of the said sensing object and makes the said portable terminal to scroll through a list of menu items and to highlight one of them as indication of selection; when the said sensing object further press down a sensing key, the said sensing key generates a corresponding ON/OFF switch signal and makes the said portable terminal to confirm the said selection of the said highlighted menu item. The important benefits of the present invention are: it provides this new menu item scrolling and selecting function while keeping the original physical size of the mobile handset and original functionality of the digit keypad of the mobile handset intact.

### FIELD OF THE INVENTION

The invention relates generally to the field of electronics technologies, and more particularly, to a sensing keypad as a user interface device of the portable terminal and its controlling method.

### BACKGROUND OF THE INVENTION

Mobile handset, as one of the portable terminals, has become a popular communication tool for many users with the development of communication technologies. Mobile handsets are evolving towards miniaturization, personalization, differentiation, intelligence, and data-convergence. Traditional mobile handset is mainly for voice communication, which has a relatively simple requirement for user interface device. Contact switch based mobile handset digit keypad has been adequately meeting this requirement. The digit keypad normally comprises ten “0-9” alphanumeric keys and several function keys. Elastic dome is placed under key. When the key is pressed down, the electrically conductive layer of the inner surface of the dome touches the contact switch beneath to make it switched ON. When push-down force is released from the key, the elastic dome returns to its original position. This mechanism enables a tactile feedback and reminds user that pushing key action is completed. The contact switch technology used in the digit keypad is mature, easy to implement, and reliable. However, as mobile handsets are evolving more towards intelligence and data-convergence, text and information input and stored on mobile handset has become more and more, which presents a new challenging requirement for user interface device. To input text on a traditional mobile handset, especially to input non-alphabetical text such as Chinese, is a very difficult task. As phone book entries in the mobile handset increases dramatically, for example, mobile handsets with 500 or even 1000 phone book entries have become more popular, scrolling and selecting desired entries using traditional 4-way navigation keys based on contact switch, has become very inconvenient.

Several new user interface devices have been implemented in mobile handset. Fro example, handwriting recognition enabled touch screen has been implemented in mobile handset to input text. There are two types of commonly used touch screens: resistive and capacitive. A resistive touch screen comprises a flexible resistive thin-film and a rigid resistive thin-film with air in the middle to separate these two layers. Its working principle is the following: when a stylus or finger applying force to the touch screen, the top resistive layer bends to the pressure and makes contacts with the bottom resistive layer, and hence closing an electronic circuit indicating the position of the stylus or finger. A capacitive touch screen works similarly, but uses change in capacitance from the pressure applied from the stylus against the touch screen to determine the position of the stylus. This new user interface of touch screen has solved the text input problem well; user interface is touch-based, where selecting desired entry item is achieved by touching that specific entry item on the touch screen. However, when there are too many entry items to be displayed all in single screen, scrolling to next screen is done easier by pressing contact switch based 4-way navigation keys. Furthermore, to keep the overall size small, most of the touch screen based mobile handset designs have one touch screen alone but no keypad. A virtual keypad is shown on the touch screen, where user has to tap virtual keys on the touch screen to dial phone numbers. Virtual keypad provides no tactile feedback, which is generally acknowledged as very inconvenient and easy to make errors. There are some mobile handsets having both touch screen and keypad, which making them big in size and difficult to carry. In summary, touch screen is difficult to meet the requirements of dialing numbers for a voice call, text input, scrolling and selecting information and small size simultaneously.

US2003025679 and EP1197835 disclosed similar user interface devices, to improve the design of having both touchpad and digit keypad. A touchpad is placed under the keypad, keypad function is intact, and dialing a number for voice call is very convenient. At the same time, the contact-less touchpad provides handwriting recognition capability to input text on a mobile handset, and mouse-like function. Sliding of a finger on the contact-less touchpad controls the cursor movement on the screen. As mobile handset needs to be small size, touchpad area is limited, therefore it is not convenient to scroll and select menu items by moving the cursor on the screen. Contact-less touchpad is thin, therefore, it does not increase the size of the mobile handset. However, combining the touchpad and keypad mechanically is not easy to implement. To keep the contact switch of keypad working, a hole is drilled for each key; thus, when pressing the key, the mechanical pillar of each key can pass the touchpad underneath successfully through the hole to pressure the dome. As the keypad design is different for different mobile phone models, the touchpad with holes needs to be designed differently to fit each mobile phone model accordingly; this increase the complexity and the cost of manufacturing. Contact-less touchpad comprises several X-directional and Y-directional electrical conducting lines; and X-directional and Y-directional electrical conducting lines have to bend over around each hole. Therefore, the contact-less touchpad's performance is affected by this non-linear behavior significantly. Furthermore, each different keypad design for each different mobile handset model causes different curviness and spacing for X-directional and Y-directional electrical conducting lines. Offset is used to solve this problem, which makes the IC of contact-less touchpad complex. Furthermore, IC of contact-less touchpad may have to be different for each different mobile handset models, which increases the complexity and cost of manufacturing. To resolve the issue of backlighting, contact-less touchpad may use transparent electrical conducting materials, which further increases the complexity and cost of manufacturing.

US2003095096 and WO03088176 disclosed similar user interface devices, where linear scrolling of menu items is achieved by moving of finger on a closed circular position sensing device, which makes scrolling and selecting large number of menu items more convenient. However, this interface device does not have keypad function, and has nothing to do with key function. To implement this user interface device on mobile handset will increase size and cost, therefore, not practical.

### SUMMARY OF THE INVENTION

The object of the present invention is to provide a sensing keypad of a portable terminal and its controlling method, which provides menu item scrolling and selecting function while keeping the original physical size of the mobile handset and original functionality of the digit keypad of the mobile handset intact.

The present invention teaches a sensing keypad of a portable terminal which has at least a keypad area, a microprocessor and a screen, comprising: at least one sensing unit placed in the keypad area of the portable terminal to form a sensing surface; at least one sensing key placed on the said sensing surface; when a sensing object moves on the said sensing surface, the said at least one sensing unit generates multidimensional coordinates signal corresponding to trajectory of movement of the said sensing object and makes the said portable terminal to scroll through a list of menu items and to highlight one of them as indication of selection; when the said sensing object further press down a sensing key, the said sensing key generates a corresponding ON/OFF switch signal and makes the said portable terminal to confirm the said selection of the said highlighted menu item.

The said sensing unit can be capacitive, generating multidimensional coordinates signal through measuring the capacitance or the change of capacitance of the sensing unit.

The said sensing unit can be resistive, generating multidimensional coordinates signal through measuring the resistance or the change of resistance of the sensing unit.

The said sensing unit can be inductive, generating multidimensional coordinates signal through measuring the inductance or the change of inductance of the sensing unit.

The said sensing unit is impedance-based, generating multidimensional coordinates signal through measuring the impedance or the change of impedance of the sensing unit.

The said sensing unit is coupled with the said at least one sensing key in the said keypad area of the portable terminal.

The said coupling of the said sensing unit and the at least one sensing key in the said keypad area of the portable terminal is electronically sharing and reusing electronic elements of the said sensing unit and of the said at least one key.

The said coupling of the said sensing unit and the said at least one key in the said keypad area of the portable terminal is mechanically sharing and reusing mechanical elements of the said sensing unit and of the said at least one key.

The said sensing units are in the same plane.

The said sensing units are in different planes.

The said sensing unit is made of electrically conductive material.

A physical and/or visual guide is placed on the said sensing surface to guide the trajectory movement of the said sensing object.

The said guide is in approximately circular shape to guide the trajectory of movement of the said sensing object approximately circular.

The said guide comprising mechanical parts with tactile feedback.

The said sensing units are placed under the surface of the said at least one key and under the surface area between the upper and lower parts of the said keys of the portable terminal.

The said sensing units are printed in the keypad area of the portable terminal.

The said sensing units are printed in rectangular, circular, ovular, triangular, polygonal shape or other shapes suitable for good electrical conductance and coupling capacitance.

The said sensing units in the same or different shapes are printed in the keypad area of the portable terminal to form sensing unit matrix.

Each sensing unit is a node of the said matrix.

The sensitivity of the sensing surface is dependent on the density of the said matrix.

The said sensing surface further comprising backlight.

Sound feedback is generated by the portable terminal when menu items are scrolled via the said menu item highlight movement on the screen of the portable terminal.

The said portable terminal is a mobile handset.

The present invention also teaches a method of controlling a sensing keypad of a portable terminal which has at least a keypad area, a microprocessor and a screen, comprising: placing at least one sensing unit in the keypad area of the portable terminal to form a sensing surface; placing at least one sensing key on the said sensing surface; when a sensing object moves on the said sensing surface, the said at least one sensing unit generates multidimensional coordinates signal corresponding to trajectory of movement of the said sensing object and makes the said portable terminal to scroll through a list of menu items and to highlight one of them as indication of selection; when the said sensing object further press down a sensing key, the said sensing key generates a corresponding ON/OFF switch signal and makes the said portable terminal to confirm the said selection of the said highlighted menu item.

The number of menu items scrolled depends on the change of the trajectory of movement of the said sensing object.

The trajectory of movement of the said sensing object is approximately linear.

The trajectory of movement of the said sensing object is nonlinear.

The trajectory of movement of the said sensing object is approximately circular.

The trajectory of movement of the said sensing object is approximately spiral.

The scrolling of the menu items is linear.

The scrolling of the menu items is nonlinear.

The scrolling velocity of the menu items is a function of the movement velocity of the said sensing object.

The scrolling velocity of the menu items is a function of the movement velocity acceleration of the said sensing object.

A plurality of menu items are displayed on the screen simultaneously.

One of the said plurality of menu items simultaneously displayed on the screen is highlighted, i.e., displayed differently from the rest menu items.

An approximately circular guide is placed on the said sensing surface to guide the trajectory of movement of the said sensing object to be approximately circular.

The important benefits of the present invention are: it provides a sensing keypad of a portable terminal and its controlling method, which provides this new menu item scrolling and selecting function while keeping the original physical size of the mobile handset and original functionality of the digit keypad of the mobile handset intact.

### BRIEF DESCRIPTION OF THE DRAWINGS

FIG. 1 shows the block diagram of a portable terminal in a preferred embodiment of the invention;

FIG. 2 illustrates a schematic of a preferred embodiment of the invention where a sensing keypad is formed by a matrix of capacitive sensing units;

FIG. 3 illustrate the schematics of three example patterns of a capacitive sensing unit applied in mobile handset;

FIG. 4 is a schematic diagram of a sensing keypad formed by the capacitive sensing units;

FIG. 5 is a schematic diagram of a preferred embodiment of a mobile handset where the sensing keypad has a sensing navigation function key;

FIG. 6 is a schematic diagram of another preferred embodiment of a mobile handset where the circular guide and hence the sensing wheel overlaps with the normal digit keypad;

FIG. 7 shows a circuit connection schematic of a sensing keypad connecting with an electrical coupling circuit and a microprocessor.

### DESCRIPTION OF THE PREFERRED EMBODIMENTS

The preferred embodiments are described in detail with drawings: The present invention teaches a sensing keypad of a portable terminal and its controlling method.

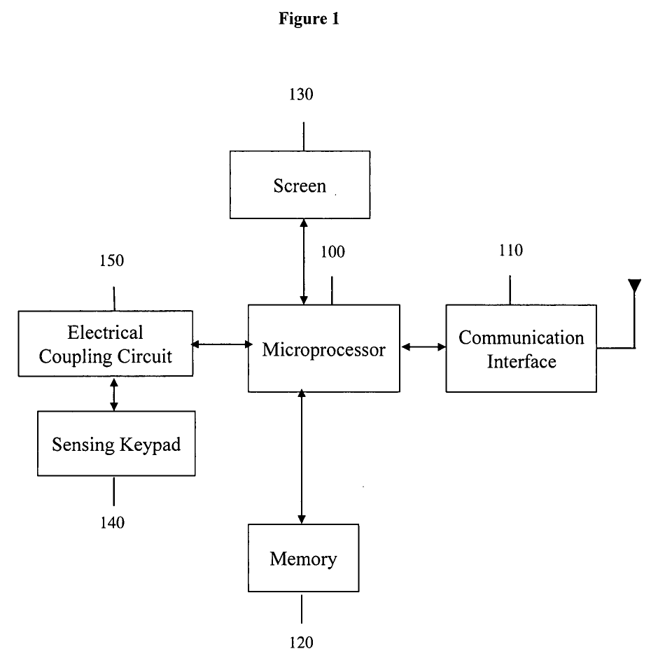

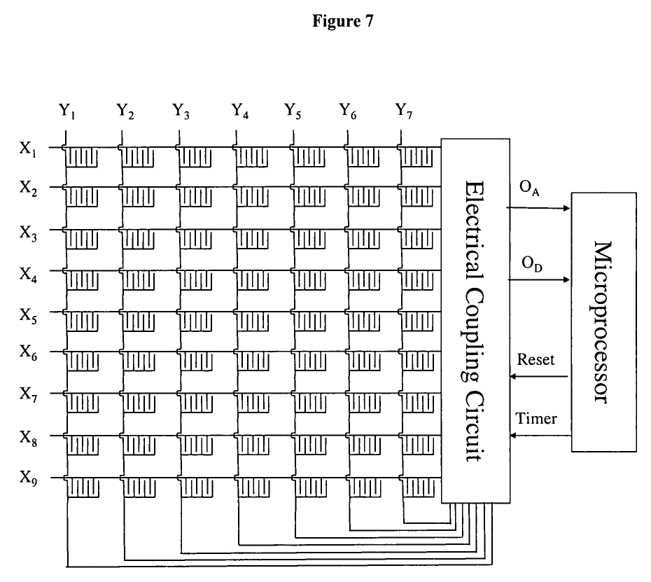

FIG. 1 shows the block diagram of a portable terminal in a preferred embodiment of the invention. The portable terminal comprises of a microprocessor (MCU) 100, a memory 120, a sensing keypad 140, an electrical coupling circuit 150, a screen 130, and a communication interface 110. The screen 130 can be used to display text, symbol, menu items or any other information. The communication interface 110 can be any apparatus with a receiver and a transmitter. User can communicate with other portable terminals via the communication interface 110 through, for example, wireless networks. FIG. 7 shows a circuit connection schematic of a sensing keypad connecting with an electrical coupling circuit and a microprocessor.

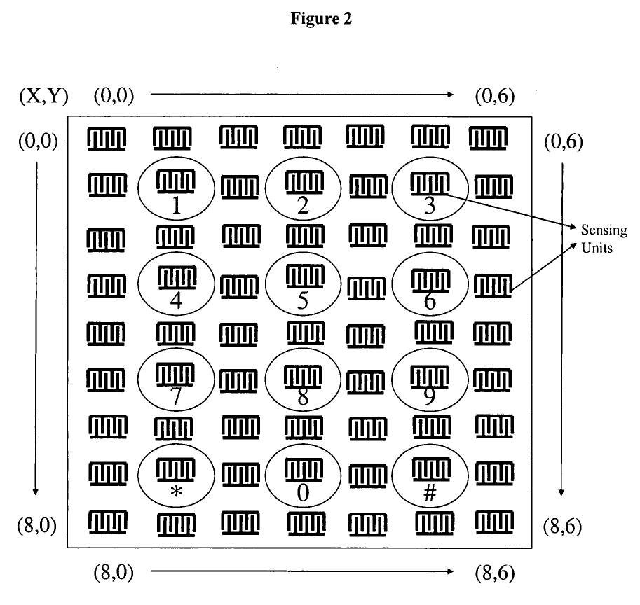

FIG. 2 illustrates a schematic of a preferred embodiment of the invention where a sensing keypad is formed by a matrix of capacitive sensing units. Each capacitive sensing unit is printed on a printed circuit board using electronically conductive material. For example, each capacitive sensing unit 210 can be formed by a pair of non-connected metal copper lines with a designed pattern. Coupling capacitance is formed between this pair of non-connected metal copper lines. Each capacitive sensing unit is connected to two conductive lines, an X-line and a Y-line. FIG. 2 illustrates an example of a 9×7 matrix. The said capacitive sensing unit matrix could be of other dimensions, which is well understood in the field and therefore not discussed in detail here. X-lines and Y-lines are not connected at the junction. This is achieved by adding an insulating layer at the junction between X-lines and Y-lines. This can also be achieved by via technology of drilling holes in the printed circuit board. This via technology is well understood in the printed circuit board field and therefore not discussed in detail here.

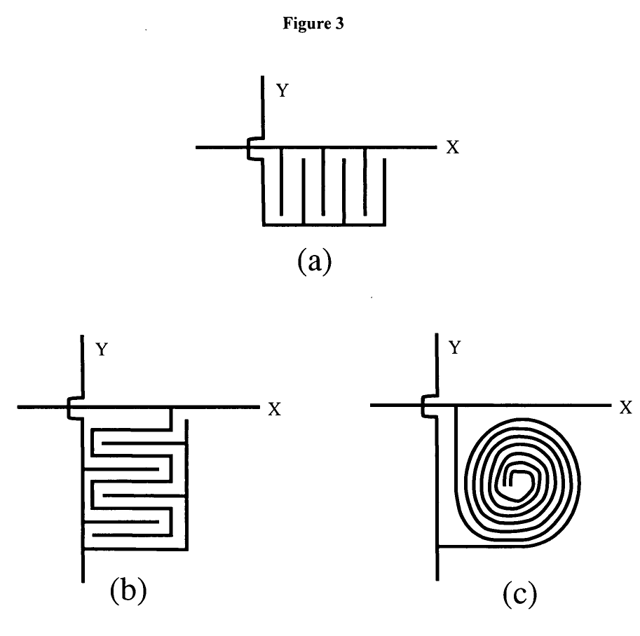

FIG. 3a, FIG. 3b, and FIG. 3c illustrate the schematics of three example patterns of a capacitive sensing unit applied in mobile handset. These patterns have many advantages. In particular, they are easy to be electrically connected with a conductor object on top. They also have good coupling capacitance when the two lines are not connected. The said capacitive sensing unit can be of many other patterns, which is well understood in the field and therefore not discussed in detail here. Each capacitive sensing unit of the preferred embodiment of the invention is printed in the pattern illustrated in the present drawing and forms the capacitive sensing unit matrix of the preferred embodiment of the invention. In normal settings, the two electrical conductive lines are not connected.

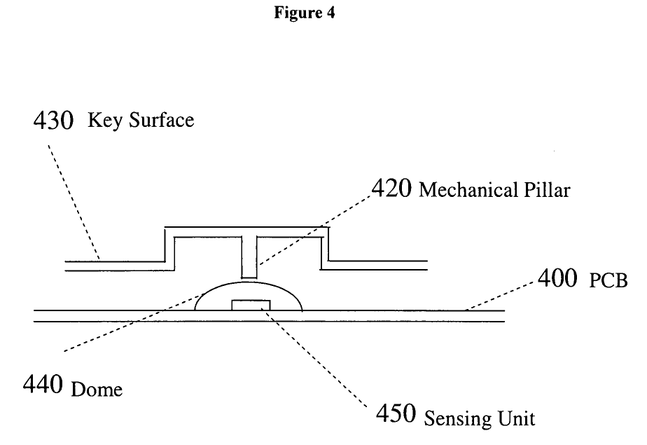

Sensing keypad is formed by placing parts on the capacitive sensing unit matrix. Some of the capacitive sensing units are coupled with mechanical parts with dome. The outer surface of these parts is printed with number and alphanumeric symbols to form sensing keys. A preferred embodiment of the invention is illustrated in FIG. 4. FIG. 4 is a schematic diagram of a sensing keypad formed by the capacitive sensing units. When a sensing object such as finger presses the key placed on top of key mechanical surface 430, the mechanical pillar 420 presses downwards on elastic dome 440, which gives resistance to the downward movement of the finger. The inner surface of dome 440 has an electrically conductive layer. When touching the capacitive sensing unit 210 on the printed circuit board 400; the electrically conductive layer of the dome connects the X-line and Y-line of the capacitive sensing unit and hence closes the said electronic circuit. The electrical coupling circuit 150 and the microprocessor 100 determine that the specific key has been pressed and move on to execute corresponding functions. When the finger pressure is released from the key, the dome 440 pushes the mechanical pillar 420 back to its original position and opens the said electronic circuit. This mechanism enables tactile feedback.

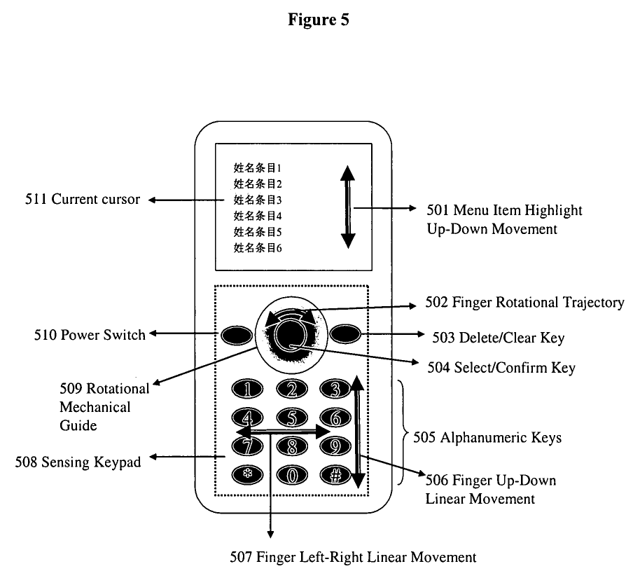

FIG. 5 is a schematic diagram of a preferred embodiment of a mobile handset where the sensing keypad 500 has a sensing navigation function key. The mobile handset comprises: menu up-down movement trajectory 501, finger rotational movement trajectory 502, delete/clear key 503, select/confirm key 504, alphanumeric keys 505, finger up-down linear movement trajectory 506, finger left-right linear movement trajectory 507, sensing keypad 508, rotational mechanical guide 509, power switch key 510, current cursor 511.

Navigation functions are implemented by a variety of finger sliding movements on the sensing keypad. The movement trajectories of linear sliding are represented by the functions:
X=X₀+Vₓt,
Y=Y₀+V_{y}t.

Where (X₀, Y₀) is the starting coordinates of the finger, (X₀, Y₀) can be any value, as sliding can start from any point on the sensing keypad. Vₓ, V_{y}, are velocity parameters.

The rightward linear movement can be:

$$\begin{matrix}X = {X}_{0} + {V}_{x} t & {V}_{x} > 0 \\ Y = {Y}_{0} & {V}_{y} = 0\end{matrix}$$

Sliding velocity can be calculated from the linear movement trajectory. The linear trajectory comprises a series of coordinates: at selected time t₀, t₁, t₂ . . . tₙ, coordinates (X₀, Y₀), (X₁, Y₁), (X₂, Y₂) . . . (Xₙ, Yₙ) of those contact points are recorded. In theory, linear movement requires Yₙ=Yₙ₋₁= . . . Y₂=Y₁=Y₀. Practical trajectory may have small deviation in the Y-direction, as long as |Yᵢ−Yᵢ₋₁|<<|Xᵢ−Xᵢ₋₁|, only X-directional velocity Vᵢₓ of the trajectory is considered, which can be calculated using this formula: Vᵢ=Vᵢₓ=(Xᵢ−Xᵢ₋₁)/(tᵢ−tᵢ₋₁), i=1,2, . . . n. The allowed deviation can be determined from experiments.

For leftward linear movement:

$$\begin{matrix}X = {X}_{0} + {V}_{x} t & {V}_{x} < 0 \\ Y = {Y}_{0} & {V}_{y} = 0\end{matrix}$$

Sliding velocity can be calculated from the linear movement trajectory, using the same method as in the case of right linear movement, with Vᵢ<0.

For upward linear movement:

$$\begin{matrix}X = {X}_{0} & {V}_{x} = 0 \\ Y = {Y}_{0} + {V}_{y} t & {V}_{y} > 0\end{matrix}$$

For downward linear movement:

$$\begin{matrix}X = {X}_{0} & {V}_{x} = 0 \\ Y = {Y}_{0} + {V}_{y} t & {V}_{y} < 0\end{matrix}$$

Up-down linear movement velocity calculation method is the same as that of left-right linear movement. When the deviation in the X-direction is within allowed limit, up-down sliding velocity can be calculated using the following formula: Vᵢ=V_{iY}=(Yᵢ−Yᵢ₋₁)/(tᵢ−tᵢ₋₁), i=1,2, . . . n.

As an example, with the preferred embodiment of the present invention, the downward navigation function implemented using a dedicated navigation key on a normal mobile phone keypad could now be realized with finger downward linear sliding movement.

As a matter of exemplification, in FIG. 5, mobile handset phone book menu entries are displayed on screen, where the third menu item labeled “name item 3” is highlighted as current item. When finger slides downward anywhere on the sensing keypad, the finger movement trajectory is processed by the microprocessor 100 and the downward linear movement is recognized using those formulas listed above. Thus a downward linear movement is determined. Accordingly, the downward linear movement of the finger is translated to scroll down the highlight bar which in turn is realized as scrolling up menu items.

The velocity of the movement of the menu items is a function of the velocity of finger sliding movement, Vₘ=f(V_{iY}). When the finger sliding movement stops at one point, the movement of menu items and hence that of the highlight bar stop too. In this way a user can select any menu item at will. At this time, if a key is pressed, the selection of the highlighted menu entry is confirmed.

Furthermore, if the selected menu item has sub-menu, the next level of menu items, such as user name and phone number, is presented for review.

Alternatively, if the selected menu item has associated data, the data is presented. If the data could not fit in a single screen, the user can again sliding finger on the sensing keypad to navigate the data shown.

The upward, leftward, and rightward navigation functions commonly implemented in normal mobile phones with specific navigation keys can all be realized with corresponding directional finger linear movement on the sensing keypad, with a method similar to what described above for downward linear movement operation.

Again as a way of exemplification, here we teach that a rotary wheel function can also be realized using the sensing keypad of the present invention. As a preferred embodiment, a circular guide is placed on the sensing keypad. The guide could be physical with different depth, material, or structure, or it could merely be a visual guide with different line pattern or color plan. A user can continuously slide his finger following the circular guide clockwise or counter-clockwise, depending on his needs, and hence executes functions normally done with dedicated mechanical rotary wheel or dedicated capacitive wheel.

Also one preferred embodiment, shown in FIG. 5, the circular guide and hence the sensing wheel is away from the 3×4 digit keypad area. Furthermore, there is an additional sensing key at the center of the circular guide.

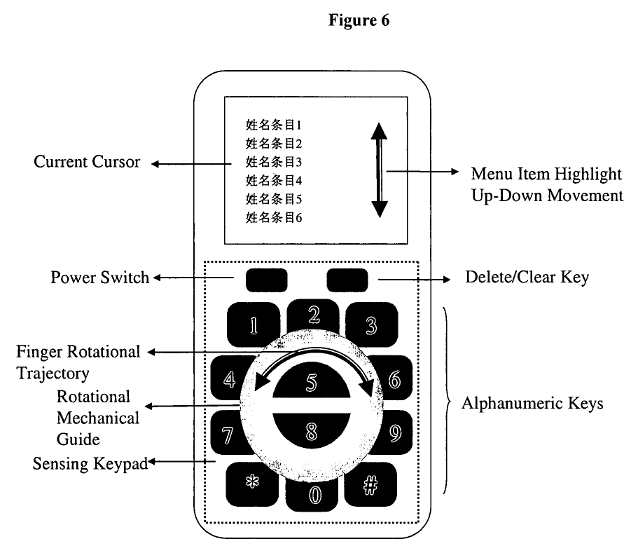

As another preferred embodiment, shown in FIG. 6, the circular guide and hence the sensing wheel overlaps with the normal 3×4 digit keypad. In FIG. 6, a sensing keypad has a big circular guide placed among alphanumeric sensing keys. This preferred embodiment saves sensing keypad surface area and therefore saves mobile handset physical space.

Those skilled in the field shall agree that, without diverse from the teachings of the present invention, many other physical and/or visual guides and designs are possible. For example, a 45-degree finger sliding movement with or without diagonal guide could be devised to realize zoom-in/out functions.

Let come back to the implementation of circular finger movement. When finger slides within the circular guide of the sensing keypad, its movement trajectory is circular. At time tᵢ contact point coordinate is (Xᵢ, Yᵢ), with proper shift, the radius of the circle can be calculated as:
Rᵢ=(Xᵢ²+Yᵢ²)^{1/2}
Furthermore, the angle of current finger touch point can be derived from
COS Ψᵢ=Xᵢ/Rᵢ,
That is,
Ψᵢ=arcos(Xᵢ/Rᵢ), and
Ψᵢ₋₁=arcos(Xᵢ₋₁/Rᵢ₋₁)
   And finger movement angular velocity is
   Φᵢ=(Ψᵢ−Ψᵢ₋₁)/(tᵢ−tᵢ₋₁)

When finger slides within the circular guide, the movement trajectory is processed by the microprocessor 100 using those formulas listed above; thus circular movement is determined, and the circular movement of the finger is converted to one-dimensional linear movement of menu items with highlights. When the circular movement is clock-wise, the highlight bar moves downwards. When the circular movement is counter-clock-wise, the highlight moves upwards. The velocity of the linear movement of the highlight bar on menu items is a function angular velocity, Vₘ=f(Φᵢ), of finger circular rotation. When finger circular rotation stops at one point, the highlight bar stops on a menu item, making it selected. If at this time a sensing key is pressed, the selection of the highlighted menu item is confirmed. Furthermore, the next level of the menu item is presented which could be, for example, a person's name and phone number.

As in the design shown in FIG. 5, the center key within the closed circular guide can be used for the selection confirmation function.

If the full data of the menu item could not fit in a single screen, the rotary finger movement could be further used to scroll display window up or down. Clockwise rotation moves to data below while counter-clockwise rotation moves to data above. Because finger can endlessly slide rotationally, scrolling large number of menu entries using the present invention is more convenient than using traditional method of laboriously pressing 4-way navigation keys.

In addition, the scrolling of menu items can be accelerated based on angular velocity or angular acceleration of finger rotational movement, making listing scrolling and selection of large number of menu entries even more efficient.

The important benefits of the present invention are: it provides this new finger rotation to scroll and select menu entry function while keeping the original physical size of the mobile handset and original functionality of the digit keypad of the mobile handset intact. In addition, it reduced the material cost of the mobile handset.

To those skilled in the field, finger up/down sliding, left/right sliding, and rotary sliding are all specific forms of finger gestures. The present invention teaches to implement finger gestures on sensing keypad for navigation and selection functions and then to implement key pressing for selection confirmation/cancellation functions.

While embodiments and applications of this invention have been shown and described, it would be apparent to those skilled in the art that many more modifications and changes than mentioned above are possible without departing from the inventive concepts herein. This invention, therefore, is not to be restricted.

1. A sensing keypad of a portable terminal which has at least a keypad area, a microprocessor and a screen, comprising:
At least one sensing unit placed in the keypad area of the portable terminal to form a sensing surface;
At least one sensing key placed on the said sensing surface;
When a sensing object moves on the said sensing surface, the said at least one sensing unit generates multidimensional coordinates signal corresponding to trajectory of movement of the said sensing object and makes the said portable terminal to scroll through a list of menu items and to highlight one of them as indication of selection;
When the said sensing object further press down a sensing key, the said sensing key generates a corresponding ON/OFF switch signal and makes the said portable terminal to confirm the said selection of the said highlighted menu item.

2. A sensing keypad of claim 1, wherein the said sensing unit can be capacitive, generating multidimensional coordinates signal through measuring the capacitance or the change of capacitance of the sensing unit.

3. A sensing keypad of claim 1, wherein the said sensing unit can be resistive, generating multidimensional coordinates signal through measuring the resistance or the change of resistance of the sensing unit.

4. A sensing keypad of claim 1, wherein the said sensing unit can be inductive, generating multidimensional coordinates signal through measuring the inductance or the change of inductance of the sensing unit.

5. A sensing keypad of claim 1, wherein the said sensing unit is impedance-based, generating multidimensional coordinates signal through measuring the impedance or the change of impedance of the sensing unit.

6. A sensing keypad of claim 1, wherein the said sensing unit is coupled with the said at least one sensing key in the said keypad area of the portable terminal.

7. A sensing keypad of claim 6, wherein the said coupling of the said sensing unit and the at least one sensing key in the said keypad area of the portable terminal is electronically sharing and reusing electronic elements of the said sensing unit and of the said at least one key.

8. A sensing keypad of claim 6, wherein the said coupling of the said sensing unit and the said at least one key in the said keypad area of the portable terminal is mechanically sharing and reusing mechanical elements of the said sensing unit and of the said at least one key.

9. A sensing keypad of claim 1, wherein the said sensing units are in the same plane.

10. A sensing keypad of claim 1, wherein the said sensing units are in different planes.

11. A sensing keypad of claim 1, wherein the said sensing unit is made of electrically conductive material.

12. A sensing keypad of claim 1, wherein a physical and/or visual guide is placed on the said sensing surface to guide the trajectory movement of the said sensing object.

13. A sensing keypad of claim 12, wherein the said guide is in approximately circular shape to guide the trajectory of movement of the said sensing object approximately circular.

14. A sensing keypad of claim 12, wherein the said guide comprising mechanical parts with tactile feedback.

15. A sensing keypad of claim 1, wherein the said sensing units are placed under the surface of the said at least one key and under the surface area between the upper and lower parts of the said keys of the portable terminal.

16. A sensing keypad of claim 15, wherein the said sensing units are printed in the keypad area of the portable terminal.

17. A sensing keypad of claim 16, wherein the said sensing units are printed in rectangular, circular, ovular, triangular, polygonal shape or other shapes suitable for good electrical conductance and coupling capacitance.

18. A sensing keypad of claim 17, wherein the said sensing units in the same or different shapes are printed in the keypad area of the portable terminal to form sensing unit matrix.

19. A sensing keypad of claim 18, wherein each sensing unit is a node of the said matrix.

20. A sensing keypad of claim 18, wherein the sensitivity of the sensing surface is dependent on the density of the said matrix.

21. A sensing keypad of claim 1, wherein the said sensing surface further comprising backlight.

22. A sensing keypad of claim 1, wherein sound feedback is generated by the portable terminal when menu items are scrolled via the said menu item highlight movement on the screen of the portable terminal.

23. A sensing keypad of claim 1, wherein the said portable terminal is a mobile handset.

24. A method of controlling a sensing keypad of a portable terminal which has at least a keypad area, a microprocessor and a screen, comprising:
Placing at least one sensing unit in the keypad area of the portable terminal to form a sensing surface;
Placing at least one sensing key on the said sensing surface;
When a sensing object moves on the said sensing surface, the said at least one sensing unit generates multidimensional coordinates signal corresponding to trajectory of movement of the said sensing object and makes the said portable terminal to scroll through a list of menu items and to highlight one of them as indication of selection;
When the said sensing object further press down a sensing key, the said sensing key generates a corresponding ON/OFF switch signal and makes the said portable terminal to confirm the said selection of the said highlighted menu item.

25. A method of claim 24, wherein the number of menu items scrolled depends on the change of the trajectory of movement of the said sensing object.

26. A method of claim 24, wherein the trajectory of movement of the said sensing object is approximately linear.

27. A method of claim 24, wherein the trajectory of movement of the said sensing object is nonlinear.

28. A method of claim 24, wherein the trajectory of movement of the said sensing object is approximately circular.

29. A method of claim 24, wherein the trajectory of movement of the said sensing object is approximately spiral.

30. A method of claim 24, wherein the scrolling of the menu items is linear.

31. A method of claim 24, wherein the scrolling of the menu items is nonlinear.

32. A method of claim 24, wherein the scrolling velocity of the menu items is a function of the movement velocity of the said sensing object.

33. A method of claim 24, wherein the scrolling velocity of the menu items is a function of the movement velocity acceleration of the said sensing object.

34. A method of claim 24, wherein a plurality of menu items are displayed on the screen simultaneously.

35. A method of claim 34, wherein one of the said plurality of menu items simultaneously displayed on the screen is highlighted, i.e., displayed differently from the rest menu items.

36. A method of claim 24, wherein an approximately circular guide is placed on the said sensing surface to guide the trajectory of movement of the said sensing object to be approximately circular.
